(19) United States
(12) Patent Application Publication
(10) Pub. No.: US 2024/0170469 A1
(43) Pub. Date: May 23, 2024

(54) DISPLAY DEVICE AND METHOD OF FABRICATING THE SAME

(71) Applicant: Samsung Display Co., LTD., Yongin-si (KR)

(72) Inventors: Hyun Wook LEE, Yongin-si (KR); Tae Hee LEE, Yongin-si (KR)

(21) Appl. No.: 18/494,387

(22) Filed: Oct. 25, 2023

(30) Foreign Application Priority Data
Nov. 23, 2022 (KR) 10-2022-0158587

(51) Int. Cl. H01L 25/16; H01L 25/075; H01L 27/12; H01L 33/62

(52) U.S. Cl. CPC H01L 25/167; H01L 25/0753; H01L 27/1225; H01L 33/62; H01L 2933/0016; H01L 2933/0066

(57) ABSTRACT

A display device including: a pixel circuit layer including a first transistor and a conductive pattern; and a display element layer on the pixel circuit layer, and including a light emitting element. The display element layer may further include: a first pixel electrode electrically connected to a first end of the light emitting element; and a second pixel electrode electrically connected to a second end of the light emitting element. The first transistor may include: a semiconductor pattern; a first gate insulating layer on the semiconductor pattern; a gate electrode on the first gate insulating layer; and a first transistor electrode and a second transistor electrode connected to the semiconductor pattern. The conductive pattern may be at a same layer as the semiconductor pattern. The first transistor electrode may be connected to the second pixel electrode by the conductive pattern.

### CROSS-REFERENCE TO RELATED APPLICATION

This application claims priority to and the benefit of Korean patent application number 10-2022-0158587, filed on Nov. 23, 2022, the entire disclosure of which is incorporated by reference herein.

### BACKGROUND

### 1. Field

Various embodiments of the present disclosure relate to a display device and a method of fabricating the display device.

### 2. Description of Related Art

Recently, as interest in information display increases, research and development on display devices have been continuously conducted.

### SUMMARY

Various embodiments of the present disclosure are directed to a display device capable of reducing or minimizing defects attributable to contact resistance and reactivity between electrodes included in the display device.

However, aspects of embodiments of the present disclosure are not limited to the above-described aspects, and various modifications are possible without departing from the spirit and scope of the present disclosure.

One or more embodiments of the present disclosure may provide a display device including: a pixel circuit layer including a first transistor and a conductive pattern; and a display element layer on the pixel circuit layer, and including a light emitting element. The display element layer may further include: a first pixel electrode electrically connected to a first end of the light emitting element; and a second pixel electrode electrically connected to a second end of the light emitting element. The first transistor may include: a semiconductor pattern; a first gate insulating layer disposed on the semiconductor pattern; a gate electrode on the first gate insulating layer; and a first transistor electrode and a second transistor electrode connected to the semiconductor pattern. The conductive pattern may be at a same layer as the semiconductor pattern. The first transistor electrode may be connected to the second pixel electrode by the conductive pattern.

In one or more embodiments, each of the semiconductor pattern and the conductive pattern may include an indium gallium zinc oxide (IGZO).

In one or more embodiments, the semiconductor pattern may be physically separated from the conductive pattern.

In one or more embodiments, the conductive pattern may be doped with a semiconductor material.

In one or more embodiments, the semiconductor pattern and the conductive pattern may be doped with a same dopant.

In one or more embodiments, the display element layer may further include: a second gate insulating layer covering a portion of a first doping area of the semiconductor pattern; and a third gate insulating layer covering one area of a second doping area of the semiconductor pattern. The first transistor electrode may be on the second gate insulating layer. The second transistor electrode may be on the third gate insulating layer.

In one or more embodiments, the first transistor electrode, the second transistor electrode, and the gate electrode may include a same material.

In one or more embodiments, an overall surface of the conductive pattern may be exposed from the first gate insulating layer, the second gate insulating layer, and the third gate insulating layer.

In one or more embodiments, the display element layer may include: a first alignment electrode under the first pixel electrode; and a second alignment electrode under the second pixel electrode. The first alignment electrode or the second alignment electrode may be directly connected to the second transistor electrode.

In one or more embodiments, the pixel circuit layer may include: a substrate; a bottom metal layer on the substrate, and overlapping a channel area of the semiconductor pattern; and a buffer layer covering the bottom metal layer. The first transistor may be on the buffer layer. The second transistor electrode may be electrically connected to the bottom metal layer through a contact hole.

In one or more embodiments, the pixel circuit layer may further include: a passivation layer covering the first transistor; and a via layer on the passivation layer. The display element layer may further include a first bank pattern on the via layer, and a second bank pattern at a the same layer as the first bank pattern. The first alignment electrode may overlap the first bank pattern. The second alignment electrode may overlap the second bank pattern. The light emitting element may be between the first bank pattern and the second bank pattern.

In one or more embodiments, the first alignment electrode or the second alignment electrode may be electrically connected to the second transistor electrode through a first contact hole passing through the passivation layer and the via layer.

In one or more embodiments, the display element layer may further include an insulating layer covering the first alignment electrode and the second alignment electrode. The first pixel electrode may overlap the first alignment electrode on the insulating layer. The second pixel electrode may overlap the second alignment electrode on the insulating layer.

In one or more embodiments, the second pixel electrode may be directly connected to the conductive pattern through a second contact hole passing through the insulating layer, the via layer, and a passivation layer covering the first transistor.

In one or more embodiments, the light emitting element may include a first semiconductor layer, a second semiconductor layer, and an active layer between the first semiconductor layer and the second semiconductor layer.

One or more embodiments of the present disclosure may provide a method of fabricating a display device, including: forming a semiconductor pattern and a conductive pattern on a substrate; forming a gate insulating layer on overall surfaces of the semiconductor pattern and the conductive pattern; exposing a portion of the semiconductor pattern and the conductive pattern by removing one area of the gate insulating layer; forming a first transistor electrode, a second transistor electrode, and a gate electrode on the semiconductor pattern; forming a via layer covering the first transistor electrode, the second transistor electrode, the gate electrode, and the conductive pattern; disposing a light emitting element on the via layer; and forming a first pixel electrode electrically connected to a first end of the light emitting element, and a second pixel electrode electrically connected to a second end of the light emitting element. The first pixel electrode may be directly connected to the conductive pattern.

In one or more embodiments, each of the semiconductor pattern and the conductive pattern may include indium gallium zinc oxide (IGZO).

In an embodiment, exposing the portion of the semiconductor pattern may include doping one area of the semiconductor pattern exposed through a process of etching another area of the gate insulating layer.

In one or more embodiments, the method may further include: forming a second contact hole by removing one area of the via layer that overlaps the second transistor electrode; and disposing, on the via layer, a first alignment electrode and a second alignment electrode spaced apart from the first alignment electrode. The first alignment electrode may be connected to the second transistor electrode through the second contact hole.

In one or more embodiments, the semiconductor pattern and the conductive pattern may include a same material, and may be concurrently formed.

### BRIEF DESCRIPTION OF THE DRAWINGS

FIG. 1 is a plan view illustrating a display device in accordance with one or more embodiments of the present disclosure.

FIG. 2 is a circuit diagram illustrating an embodiment of a sub-pixel included in the display device of FIG. 1.

FIG. 3 is a sectional view illustrating an embodiment of a sub-pixel included in the display device of FIG. 1.

FIGS. 4 to 11 are sectional views schematically illustrating a method of fabricating the display device in accordance with one or more embodiments of the present disclosure.

FIG. 12 is a sectional view illustrating first to third sub-pixels of FIG. 1 in accordance with one or more embodiments.

FIGS. 13 and 14 are diagrams each illustrating a light emitting element in accordance with one or more embodiments.

### DETAILED DESCRIPTION

Various embodiments of the present disclosure will hereinafter be described in detail with reference to the accompanying drawings. The same reference numerals are used throughout the different drawings to designate the same components, and repetitive description of the same components will be omitted.

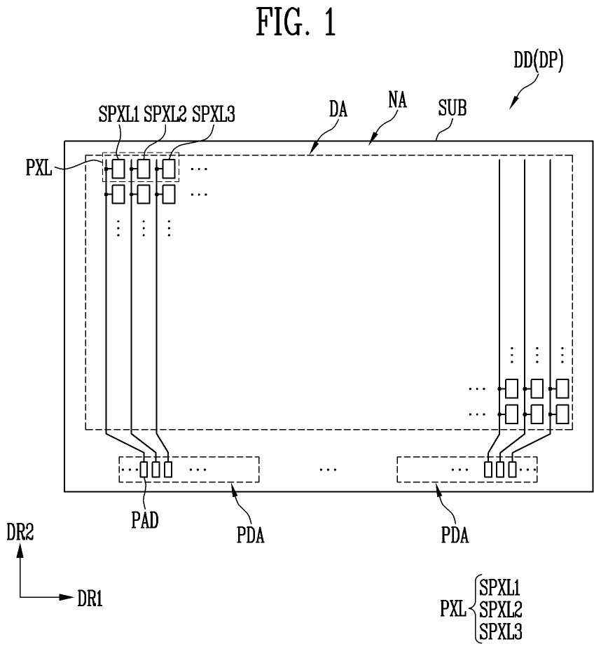

FIG. 1 is a plan view illustrating a display device DD in accordance with one or more embodiments of the present disclosure. FIG. 1 illustrates a display panel DP provided in the display device DD.

FIG. 1 schematically illustrates the structure of the display panel DP, focused on a display area DA. In one or more embodiments, at least one driving circuit (e.g., at least one of a scan driver and a data driver), lines, and/or pads may be further provided on the display panel DP.

If the display device DD is an electronic device having a display surface on at least one surface thereof, e.g., a smartphone, a television, a tablet PC, a mobile phone, a video phone, an electronic reader, a desktop PC, a laptop PC, a netbook computer, a workstation, a server, a PDA, a portable multimedia player (PMP), an MP3 player, a medical appliance, a camera, or a wearable device, the present disclosure may be applied to the display device DD.

Referring to FIG. 1, the display panel DP may include a substrate SUB (or a base layer), and a pixel PXL provided on the substrate SUB.

The display panel DP may have various shapes. For example, the display panel DP may be provided in the form of a rectangular plate, but the present disclosure is not limited thereto. For instance, the display panel DP may have a circular or elliptical shape. Furthermore, the display panel DP may have one or more angled corners and/or curved corners. For convenience of explanation, FIG. 1 illustrates that the display panel DP has a rectangular plate shape. In addition, in FIG. 1, an extension direction (e.g., a horizontal direction) of a long side of the display panel DP is designated as a first direction DR1, and an extension direction (e.g., a vertical direction) of a short side thereof is designated as a second direction DR2.

The substrate SUB may form a base of the display panel PD and may be a rigid or flexible substrate or film. For example, the substrate SUB may be a rigid substrate made of glass or reinforced glass, a flexible substrate (or a thin film) formed of plastic or metal, or at least one insulating layer. The material and/or properties of the substrate SUB are not particularly limited.

The substrate SUB (or the display panel DP) may include a display area DA configured to display an image, and a non-display area NA located in an area other than the display area DA, along an edge or periphery of the display area DA. The display area DA may form a screen on which an image is displayed. The non-display area NA may be located on at least one side of the display area DA. For example, the non-display area NA may enclose the display area DA, but the present disclosure is not limited thereto.

The pixel PXL may be disposed in the display area DA on the substrate SUB. The non-display area NA may be disposed around the display area DA. Various lines, pads, and/or internal circuits that are connected to the pixels PXL of the display area DA may be disposed in the non-display area NA. The non-display area NA may include a pad area PDA, and pads PAD may be disposed in the pad area PDA. For example, the pads PAD may be connected to a driving circuit such as a source driver or a timing controller that is mounted on a flexible circuit substrate. In the case where the display panel DP is connected to a plurality of source drivers, the pad area PDA may correspond to each of the source drivers.

Each pixel PXL may be connected to a corresponding one of the pads PAD through a data line DL, and may receive a data signal from the source driver. In the case where an internal circuit (e.g., a gate driver) is provided in the display panel DP, the internal circuit may be connected to the pads PAD. Although FIG. 1 illustrates that the pads PAD (or the pad area PDA) are disposed on only a lower side of the display panel DP, the present disclosure is not limited thereto. For example, the pads PAD may be disposed on each of the upper and lower sides of the display panel DP.

In the description of the embodiments of the present disclosure, the term “connection (or coupling)” may collectively refer to physical and/or electrical connection (or coupling). Furthermore, the term “connection (or coupling)” may collectively refer to direct or indirect connection (or coupling) and integral or non-integral connection (or coupling).

Each of the pixels PXL may include sub-pixels SPXL1 to SPXL3. For example, the pixel PXL may include a first sub-pixel SPXL1, a second sub-pixel SPXL2, and a third sub-pixel SPXL3.

Each of the sub-pixels SPXL1 to SPXL3 may emit a certain color of light. In one or more embodiments, the sub-pixels SPXL1 to SPXL3 may emit different colors of light. For example, the first sub-pixel SPXL1 may emit a first color of light. The second sub-pixel SPXL2 may emit a second color of light. The third sub-pixel SPXL3 may emit a third color of light. For example, the first sub-pixel SPXL1 may be a red pixel configured to emit red light, the second sub-pixel SPXL2 may be a green pixel configured to emit green light, and the third sub-pixel SPXL3 may be a blue pixel configured to emit blue light. However, the present disclosure is not limited to the foregoing.

In one or more embodiments, the first sub-pixel SPXL1, the second sub-pixel SPXL2, and the third sub-pixel SPXL3 may respectively include, as light sources, a light emitting element related to the first color, a light emitting element related to the second color, and a light emitting element related to the third color, so that the first, second, and third sub-pixels SPXL1, SPXL2, and SPXL3 may respectively emit the first color of light, the second color of light, and the third color of light. In one or more embodiments, the first sub-pixel SPXL1, the second sub-pixel SPXL2, and the third sub-pixel SPXL3 may respectively include light emitting elements configured to emit the same color of light, and color conversion layers and/or color filters pertaining to different colors may be disposed on the respective light emitting elements so that the first, second, and third sub-pixels SPXL1, SPXL2, and SPXL3 may respectively emit the first color of light, the second color of light, and the third color of light. However, the colors, the types, and/or the number of sub-pixels SPXL1 to SPXL3 that form each pixel PXL are not particularly limited. In other words, the color of light to be emitted from each pixel PXL may be changed in various ways.

The sub-pixels SPXL1 to SPXL3 may be regularly arranged according to a stripe or a PENTILE® structure, or the like. The PENTILE® pixel arrangement structure may be referred to as an RGBG matrix structure (e.g., a PENTILE® matrix structure or an RGBG structure (e.g., a PENTILE® structure)). PENTILE® is a registered trademark of Samsung Display Co., Ltd., Republic of Korea. For example, the first, second, and third sub-pixels SPXL1, SPXL2, and SPXL3 may be sequentially repeatedly disposed along a first direction DR1, and also may be repeatedly disposed along a second direction DR2. At least one first sub-pixel SPXL1, at least one second sub-pixel SPXL2, and at least one third sub-pixel SPXL3 that are disposed adjacent to each other may form one pixel PXL that may emit various colors of light. The arrangement structure of the sub-pixels SPXL1 to SPXL3 is not limited thereto, and the sub-pixels SPXL1 to SPXL3 may be arranged in the display area DA in various structures and/or schemes.

In one or more embodiments, each of the sub-pixels SPXL1 to SPXL3 may be formed of an active pixel. For example, each of the sub-pixels SPXL1 to SPXL3 may include at least one light source (e.g., a light emitting element) that is driven by a control signal (e.g., a scan signal and a data signal) and/or a power supply (e.g., a first power supply and a second power supply). However, the types, structures, and/or driving schemes of the sub-pixels SPXL1 to SPXL3 applicable to the display device are not particularly limited.

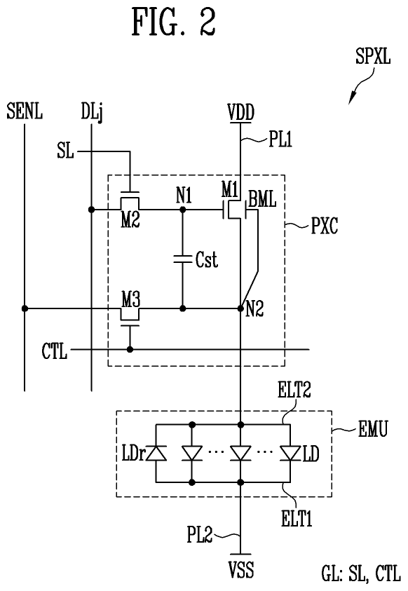

FIG. 2 is a circuit diagram illustrating an embodiment of a sub-pixel included in the display device of FIG. 1.

For example, FIG. 2 illustrates an electrical connection relationship of components included in each of the sub-pixels SPXL1, SPXL2, and SPXL3 that may be employed in an active matrix type display device in accordance with one or more embodiments. Here, the connection relationship of the components of each of the sub-pixels SPXL1, SPXL2, and SPXL3 is not limited thereto.

Hereinafter, the first sub-pixel SPXL1, the second sub-pixel SPXL2, and the third sub-pixel SPXL3 are collectively referred to as a sub-pixel SPXL.

For example, the sub-pixel of FIG. 2 may be any one of the sub-pixels SPXL1 to SPXL3 illustrated in FIG. 1. The sub-pixels SPXL1 to SPXL3 arranged in each display area DA may have a substantially identical or similar configuration.

Referring to FIG. 2, the sub-pixel SPXL may be connected to at least one gate line GL, a data line DL, a first power line PL1, and a second power line PL2. Furthermore, the pixel PXL may be selectively further connected to at least one other power line and/or signal line.

The sub-pixel SPXL may include an emission component EMU configured to emit light having a luminance corresponding to a data signal. Furthermore, the pixel PXL may selectively further include a pixel circuit PXC configured to drive the emission component EMU.

The pixel circuit PXC may be connected to the corresponding gate line GL (e.g., a scan line SL and a control line CTL) and the corresponding data line DL, and may be connected between the first power line PL1 and the emission component EMU. For example, the pixel circuit PXC may be connected to a scan line SL to which a scan signal may be supplied, the data line DL to which a data signal may be supplied, the first power line PL1 to which a voltage of a first power supply VDD may be applied, and a second pixel electrode ELT2 of the emission component EMU. Furthermore, the pixel circuit PXC may be selectively further connected to a control line CTL to which a scan signal may be supplied, and a sensing line SENL which is connected to a reference power supply (or an initialization power supply) or a sensing circuit in response to a display period or a sensing period. In this case, the gate line GL may include the scan line SL and the control line CTL.

The pixel circuit PXC may include at least one transistor and at least one capacitor. For example, the pixel circuit PXC may include a first transistor M1, a second transistor M2, a third transistor M3, and a capacitor Cst.

The first transistor M1 may be connected between the first power line PL1 and a second node N2. The second node N2 may be a node to which the pixel circuit PXC and the emission component EMU are connected, and, for example, may be a node (referred to as “source node of the first transistor M1” or “anode node of the sub-pixel SPXL”) to which a first electrode (e.g., a source electrode) of the first transistor M1 and a second pixel electrode ELT2 of the emission component EMU are connected. A gate electrode of the first transistor M1 may be connected to a first node N1. The first transistor M1 may control driving current to be supplied to the emission component EMU in response to a voltage of the first node N1. In other words, the first transistor M1 may be a driving transistor of the pixel PXL.

In one or more embodiments, the first transistor M1 may selectively further include a bottom metal layer BML (or a back gate electrode). The gate electrode of the first transistor M1 and the bottom metal layer BML may overlap each other with an insulating layer interposed therebetween. In one or more embodiments, the bottom metal layer BML may be connected to one electrode of the first transistor M1, e.g., the source electrode of the first transistor M1.

An embodiment in which the first transistor M1 includes the bottom metal layer BML may employ a back-biasing technique (or a sync technique) of shifting a threshold voltage of the first transistor M1 in a negative direction or a positive direction by applying a back-biasing voltage to the bottom metal layer BML of the first transistor M1. In the case where the bottom metal layer BML is disposed under a semiconductor pattern that forms a channel of the first transistor M1 to block light from being incident on the semiconductor pattern, operating characteristics of the first transistor M1 may be stabilized.

The second transistor M2 may be connected between the data line DL and the first node N1. A gate electrode of the second transistor M2 may be connected to the scan line SL. When a scan signal of a gate-on voltage (e.g., a high-level voltage) is supplied from the scan line SL, the second transistor M2 is turned on to connect the data line DL with the first node N1.

During each frame period, a data signal of a corresponding frame is supplied to the data line DL, and the data signal is transmitted to the first node N1 through the second transistor M2 during a period in which the scan signal having the gate-on voltage is supplied to the scan line SL. In other words, the second transistor M2 may be a switching transistor configured to transmit each data signal to the interior of the pixel PXL.

One electrode of the capacitor Cst may be connected to the first node N1, and a remaining electrode thereof may be connected to the second node N2. The capacitor Cst may be charged with a voltage corresponding to a data signal to be supplied to the first node N1 during each frame period.

The third transistor M3 may be connected between the second node N2 and the sensing line SENL. A gate electrode of the third transistor M3 may be connected to the control line CTL. When a control signal having a gate-on voltage (e.g., a high-level voltage) is supplied from the control line CTL, the third transistor M3 may be turned on so that a reference voltage (or an initialization voltage) supplied to the sensing line SENL may be transmitted to the second node N2, or the voltage of the second node N2 may be transmitted to the sensing line SENL. The voltage of the second node N2 that is transmitted to the sensing circuit through the sensing line SENL may be provided to an external circuit (e.g., a timing controller), and may be used to compensate for a characteristic deviation of the sub-pixel SPXL.

Although FIG. 2 illustrates that all of the transistors included in the pixel circuit PXC are N-type transistors, the present disclosure is not limited thereto. For example, at least one of the first, second, and third transistors M1, M2, and M3 may be changed to a P-type transistor. The structure and driving method of the pixel PXL may be changed in various ways depending on the embodiment.

The emission component EMU may include a first pixel electrode ELT1, a second pixel electrode ELT2, and at least one light emitting element LD, which are connected between the first power line PL1 and the second power line PL2. For example, the emission component EMU may include a second pixel electrode ELT2 connected to the first power line PL1 through the first transistor M1, a first pixel electrode ELT1 connected to the second power line PL2, and at least one light emitting element LD connected between the first pixel electrode ELT1 and the second pixel electrode ELT2. In one or more embodiments, the emission component EMU may include a plurality of light emitting elements LD that are connected in parallel to each other between the first pixel electrode ELT1 and the second pixel electrode ELT2.

The voltage of the first power supply VDD to be supplied to the first power line PL1 and the voltage of a second power supply VSS to be supplied to the second power line PL2 may have different potentials. For example, the first power supply VDD may be a high-potential power supply, and the second power supply VSS may be a low-potential power supply. A difference in potential between the first power supply VDD and the second power supply VSS may be set to a value equal to or greater than the threshold voltage of the light emitting elements LD. In this case, the first pixel electrode ELT1 may be an anode electrode of the emission component EMU, and the second pixel electrode ELT2 may be a cathode electrode of the emission component EMU.

Each light emitting element LD may be connected in a forward direction between the first power supply VDD and the second power supply VSS, and may form a valid light source. Such valid light sources may collectively form the emission component EMU of the pixel PXL.

The light emitting elements LD may emit light at a luminance corresponding to driving current supplied thereto through the pixel circuit PXC. During each frame period, the pixel circuit PXC may supply driving current corresponding to a data signal to the emission component EMU. The driving current supplied to the emission component EMU may be divided into parts that flow into the light emitting elements LD. Hence, each of the light emitting elements LD may emit light having a luminance corresponding to current applied thereto, so that the emission component EMU may emit light having a luminance corresponding to the driving current. In one or more embodiments, the light emitting element LD may have a rod-like shape, a bar-like shape, or a pillar-like shape. For example, the light emitting element LD may have a rod-like shape, a bar-like shape, or a pillar-like shape that is short with respect to the longitudinal direction (or has an aspect ratio less than 1).

In one or more embodiments, the emission component EMU may further include at least one invalid light source. For example, the emission component EMU may further include an invalid light emitting element LDr, which is connected in a reverse direction between the first and second pixel electrodes ELT1 and ELT2 or is incompletely connected between the first and second electrodes ELT1 and ELT2.

Although FIG. 2 illustrates an embodiment in which the pixel PXL includes the emission component EMU having a parallel structure, the present disclosure is not limited thereto. For example, in one or more embodiments, the sub-pixel SPXL may include an emission component EMU having a series structure or a series/parallel structure. In this case, the emission component EMU may include a plurality of light emitting elements LD that are connected in series or series/parallel to each other between the first pixel electrode ELT1 and the second pixel electrode ELT2. In one or more embodiments, the sub-pixel SPXL may include only a single light emitting element LD connected between the first pixel electrode ELT1 and the second pixel electrode ELT2.

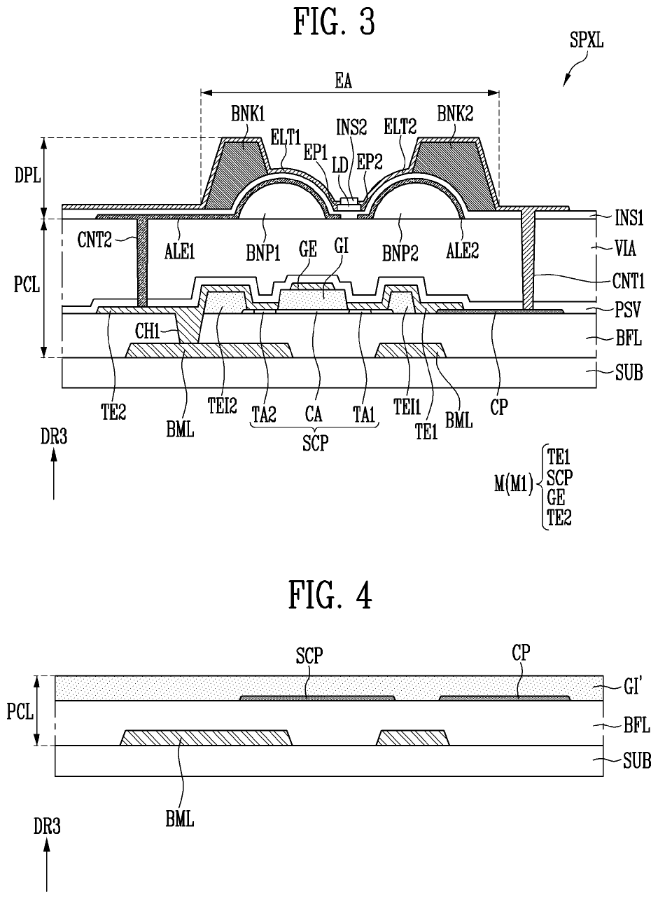

FIG. 3 is a sectional view illustrating an embodiment of a sub-pixel SPXL included in the display device of FIG. 1. FIG. 3 illustrates a first transistor M1 (refer to FIG. 2) and a conductive pattern CP, as an example of circuit elements that may be disposed on the pixel circuit layer PCL.

Referring to FIG. 3, the sub-pixel SPXL (or the display device) may include a pixel circuit layer PCL and a display element layer DPL that are disposed on the substrate SUB.

The pixel circuit layer PCL may include a first transistor M1, a conductive pattern CP, and a plurality of insulating layers BFL, GI, PSV, and VIA. The first transistor M1 may include a semiconductor pattern SCP, a gate electrode GE, a first transistor electrode TE1, and a second transistor electrode TE2. The first transistor M1 may selectively further include a bottom metal layer BML.

A first conductive layer may be disposed between the substrate SUB and the buffer layer BFL. The first conductive layer may include a conductive material. The conductive material may include at least one selected from the group of various metal materials including silver (Ag), magnesium (Mg), aluminum (Al), platinum (Pt), palladium (Pd), gold (Au), nickel (Ni), neodymium (Nd), iridium (Ir), chrome (Cr), titanium (Ti), molybdenum (Mo), copper (Cu), etc., and/or an alloy thereof. The first conductive layer may have a single-layer structure, a double-layer structure, or a multilayer structure.

The first conductive layer may include the bottom metal layer BML. The bottom metal layer BML and the second transistor electrode TE2 of the first transistor M1 may overlap each other with the buffer layer BFL interposed therebetween. The bottom metal layer BML may be disposed under a second transistor electrode TE2 of the first transistor M1.

Although FIG. 3 illustrates that the bottom metal layer BML does not overlap a channel area of the semiconductor pattern SCP, at least a portion of the bottom metal layer BML may overlap the semiconductor pattern SCP. In this case, the bottom metal layer BML may function as a light shielding pattern, so that the operating characteristics of the first transistor M1 can be stabilized. Furthermore, the bottom metal layer BML may be physically and/or electrically connected with the second transistor electrode TE2 of the first transistor M1, which will be described below, through a contact hole CH of an insulating layer (e.g., the buffer layer BFL). Hence, the threshold voltage of the first transistor M1 may be shifted in a negative direction or a positive direction. Although FIG. 3 illustrates that the bottom metal layer BML is connected to the second transistor electrode TE2, the present disclosure is not limited thereto. For example, the bottom metal layer BML may be physically and/or electrically connected to the first transistor electrode TE1.

In one or more embodiments, the first transistor M1 may not include the bottom metal layer BML. In this case, the buffer layer BFL may be directly located on the substrate SUB.

The buffer layer BFL may be located on the substrate SUB and cover the bottom metal electrode BML.

The buffer layer BFL may prevent impurities from diffusing into the pixel circuit layer PCL. The buffer layer BFL may include inorganic insulating material. For example, the inorganic material may include at least one selected from the group of silicon nitride (SiNₓ), silicon oxide (SiOₓ), silicon oxynitride (SiOxNy), and/or a metal oxide such as aluminum oxide (AlOₓ). The buffer layer BFL may be omitted depending on the material of the substrate SUB or processing conditions.

The semiconductor pattern SCP of the first transistor M1 may be located on the buffer layer BFL. The semiconductor pattern SCP may include a first area TA1 (or a first doped area) connected to the first transistor electrode TE1, a second area TA2 (or a second doped area) connected to the second transistor electrode TE2, and a channel area CA formed between the first area TA1 and the second area TA2.

The semiconductor pattern SCP may be a semiconductor pattern formed of one or more materials selected from the group of polycrystalline silicon, amorphous silicon, an oxide semiconductor, etc. In one or more embodiments, the semiconductor pattern SCP may include at least one selected from among an indium gallium zinc oxide (IGZO) and/or an indium zinc titanium oxide (ITZO).

The channel area CA may overlap the gate electrode GE of the first transistor M1 in a thickness direction of the substrate SUB (e.g., the third direction DR3). The channel area CA may be a semiconductor pattern doped with no impurity, and may be an intrinsic semiconductor.

The first area TA1 and the second area TA2 may be a semiconductor pattern doped with an impurity. In one or more embodiments, the first area TA1 and the second area TA2 may be doped to be an N type. The first area TA1 may contact one area of the first transistor electrode TE1. The second area TA2 may contact one area of the second transistor electrode TE2.

A gate insulating layer GI (or a first gate insulating layer) may be disposed on the semiconductor pattern SCP. The gate insulating layer GI may be partially disposed on the semiconductor pattern SCP. In one or more embodiments, the gate insulating layer GI may be disposed to overlap the channel area CA of the semiconductor pattern SCP.

The gate insulating layer GI may include inorganic material. However, the present disclosure is not limited to the foregoing, and the gate insulating layer GI may include organic material. For example, the organic layer may include, for example, at least one selected from among polyacrylate resin, epoxy resin, phenolic resin, polyamide resin, polyimide rein, unsaturated polyester resin, poly-phenylen ether resin, poly-phenylene sulfide resin, and/or benzocyclobutene resin.

The gate electrode GE may be disposed on the gate insulating layer GI. The gate electrode GE may be disposed on the gate insulating layer GI to overlap the channel area CA of the semiconductor pattern SCP.

A first electrode insulating layer TEI1 (or a second gate insulating layer) and a second electrode insulating layer TEI2 (or a third gate insulating layer) may be disposed on the buffer layer BFL. The first electrode insulating layer TEI1 may overlap one end of the semiconductor pattern SCP. The second electrode insulating layer TEI2 may overlap the other end of the semiconductor pattern SCP. The first electrode insulating layer TEI1 and the second electrode insulating layer TEI2 may be disposed on respective opposite sides of the gate insulating layer GI.

The first electrode insulating layer TEI1 and the second electrode insulating layer TEI2 each may include inorganic material. However, the present disclosure is not limited to the foregoing, and the first electrode insulating layer TEI1 and the second electrode insulating layer TEI2 each may include organic material. In one or more embodiments, the first electrode insulating layer TEI1 and the second electrode insulating layer TEI2 may have the same material as the gate insulating layer GI.

In FIG. 3, the gate insulating layer GI, the first electrode insulating layer TEI1, and the second electrode insulating layer TEI2 are illustrated as being physically separated from each other, but may be integrally formed with each other. In this case, openings may be formed in the gate insulating layer GI to correspond to the first area TA1 and the second area TA2 of the semiconductor pattern SCP.

The first area TA1 of the semiconductor pattern SCP may be disposed between the gate insulating layer GI and the first electrode insulating layer TEI1. The second area TA2 of the semiconductor pattern SCP may be disposed between the second electrode insulating layer TEI2 and the gate insulating layer GI.

The conductive pattern CP may be disposed on the buffer layer BFL. The conductive pattern CP may be disposed to be spaced from the semiconductor pattern SCP. The first transistor electrode TE1 may directly contact one area of the conductive pattern CP.

The second pixel electrode ELT2 (or the first pixel electrode ELT1) to be described below may be connected to the first transistor electrode TE1 through the conductive pattern CP.

In one or more embodiments, the conductive pattern CP may be disposed to be spaced from the first electrode insulating layer TEI1.

In one or more embodiments, the conductive pattern CP may include semiconductor oxide. In one or more embodiments, the conductive pattern CP may be formed of a conductor having high charge mobility similar to that of a metal. For example, the conductive pattern CP may include indium gallium zinc oxide (IGZO), but is not limited thereto, and may include at least one selected from among indium-zinc oxide (IZO), indium oxide (InOx), indium gallium hafnium oxide (IGHO), and/or indium-gallium-tin oxide (IGSO).

In one or more embodiments, the conductive pattern CP may have the same materials as the semiconductor pattern SCP. For example, the conductive pattern CP and the semiconductor pattern SCP may include indium gallium zinc oxide (IGZO).

In one or more embodiments, the conductive pattern CP and the semiconductor pattern SCP may be concurrently (e.g., simultaneously) formed through the same process, but the present disclosure is not limited thereto.

In one or more embodiments, the conductive pattern CP may be doped. In one or more embodiments, the conductive pattern CP may be doped to be an N+ type dopant.

The first transistor electrode TE1 and the second transistor electrode TE2 may be disposed on the buffer layer BFL and the first and second electrode insulating layer TEI1 and TEI2. The first transistor electrode TE1 may be disposed on the first electrode insulating layer TEI1. The second transistor electrode TE2 may be disposed on the second electrode insulating layer TEI2. In a cross-sectional view, the first and second transistor electrodes TE1 and TE2 may have surface profiles that respectively correspond to the shapes of the first and second electrode insulating layers TEI1 and TEI2.

The first transistor electrode TE1 and the second transistor electrode TE2 may be electrically connected to the semiconductor pattern SCP. In one or more embodiments, the first transistor electrode TE1 may directly contact the first area TA1 of the semiconductor pattern SCP. The second transistor electrode TE2 may directly contact the second area TA2 of the semiconductor pattern SCP.

At least one area of the first transistor electrode TE1 may be disposed on the conductive pattern CP. In other word, the first transistor electrode TE1 may directly contact at least one area of the conductive pattern CP.

The second transistor electrode TE2 may be brought into contact with or connected to the bottom metal layer BML through a contact hole CH passing through the buffer layer BFL.

The first transistor electrode TE1 and the second transistor electrode TE2 may be formed through the same process as that of the gate electrode GE. The first transistor electrode TE1 and the second transistor electrode TE2 may include a metal such as aluminum (Al), silver (Ag), chrome (Cr), titanium (Ti), tantalum (Ta), and molybdenum (Mo), an alloy thereof, a nitride thereof, a conductive metal oxide, transparent conductive material, and/or the like.

In one or more embodiments, the first transistor electrode TE1, the second transistor electrode TE2, and the gate electrode GE may be disposed on (or at) the same layer.

The passivation layer PSV may be disposed on the first transistor electrode TE1, the gate electrode GE, the gate insulating layer GI, the second transistor electrode TE2, the conductive pattern CP, the buffer layer BFL, and may be disposed on an overall surface of the substrate SUB. Although the passivation layer PSV may include inorganic material in a manner similar to that of the gate insulating layer GI, the present disclosure is not limited thereto. The passivation layer PSV may include organic material. The passivation layer PSV may be provided in a single-layer structure, or may be provided in a multilayer structure having two or more layers. In one or more embodiments, the passivation layer PSV may be omitted.

A via layer VIA may be disposed on the passivation layer PSV. The via layer VIA may be disposed on the overall surface of the substrate SUB. The via layer VIA may include organic material. The via layer VIA may provide a planar surface to the top or may planarize the step difference created by layers therebelow.

The display element layer DPL may be located on the via layer VIA.

The display element layer DPL may include first and second bank patterns BNP1 and BNP2, first and second alignment electrodes ALE1 and ALE2, first and second pixel electrodes ELT1 and ELT2, a first insulating layer INS1, the first bank BNK1, and the second bank BNK2.

The first and second bank patterns BNP1 and BNP2 may be disposed on the via layer VIA. Each of the first and second bank patterns BNP1 and BNP2 may have a semicircular cross-sectional shape that is reduced in width from one surface (e.g., an upper surface) of the via layer VIA upward in the third direction DR3. In one or more embodiments, each of the first and second bank patterns BNP1 and BNP2 may have a cross-sectional shape such as a trapezoidal shape, a semi-elliptical shape, or a hemispherical shape that is reduced in width from one surface of the via layer VIA upward in the third direction DR3. In a cross-sectional view, the shape of each of the first and second bank patterns BNP1 and BNP2 is not limited to the foregoing examples, and may be changed in various ways within a range in which the efficiency of light emitted from each of the light emitting elements LD can be enhanced.

Each of the first and second bank patterns BNP1 and BNP2 may include inorganic material or organic material, and may have a single-layer structure or a multilayer structure. In one or more embodiments, the first and second bank patterns BNP1 and BNP2 may be omitted. For example, a structure corresponding to the first and second bank patterns BNP1 and BNP2 may be formed on the via layer VIA.

The first and second alignment electrodes ALE1 and ALE2 may be disposed on the via layer VIA and the first and second bank patterns BNP1 and BNP2.

The first alignment electrode ALE1 may be disposed on the first bank pattern BNP1. The second alignment electrode ALE2 may be disposed on the second bank pattern BNP2. In a cross-sectional view, the first and second alignment electrodes ALE1 and ALE2 may respectively have surface profiles corresponding to the shapes of the first and second bank patterns BNP1 and BNP2.

The first and second alignment electrodes ALE1 and ALE2 each may include conductive material having a reflectivity to enable light emitted from the light emitting element LD to travel in an image display direction (e.g., in the third direction DR3) of the display device. Each of the first and second alignment electrodes ALE1 and ALE2 may have a single-layer structure or a multilayer structure. In one or more embodiments, the first and second alignment electrodes ALE1 and ALE2 each may have a double-layer structure or a multilayer structure to reduce line resistance (or contact resistance), and may include one or more materials selected from among copper (Cu), molybdenum (Mo), tungsten (W), aluminum neodymium (AlNd), titanium (Ti), aluminum (Al), silver (Ag), and/or an alloy thereof.

The first alignment electrode ALE1 may be brought into contact with or connected to the second transistor electrode TE2 of the first transistor M1 through a second contact hole CNT2 passing through the via layer VIA and the passivation layer PSV. Although FIG. 3 illustrates that the first alignment electrode ALE1 is connected to the second transistor electrode TE2 through the second contact hole CNT2, the present disclosure is not limited thereto. The second alignment electrode ALE2 may be connected to the second transistor electrode TE2 through the second contact hole CNT2.

The first and second alignment electrodes ALE1 and ALE2 may be used as alignment electrodes for aligning the light emitting elements LD during a process of fabricating the display device. After the first and second alignment electrodes ALE1 and ALE2 are used as electrodes for aligning the light emitting elements LD, the voltage of the first power supply VDD (or the voltage of the second power supply VSS) may be applied to the first alignment electrode ALE1. The voltage of the second power supply VSS (or the voltage of the first power supply VDD) may be applied to the second alignment electrode ALE2. In one or more embodiments, after the first and second alignment electrodes ALE1 and ALE2 are used as electrodes for aligning the light emitting elements LD, the first and second alignment electrodes ALE1 and ALE2 may float.

The first and second alignment electrodes ALE1 and ALE2 may include one or more selected from among silver (Ag), magnesium (Mg), aluminum (Al), platinum (Pt), palladium (Pd), gold (Au), nickel (Ni), neodymium (Nd), iridium (Ir), chrome (Cr), titanium (Ti), and/or an alloy thereof. The present disclosure is not limited to the foregoing example.

The second transistor electrode TE2 may include materials having properties similar to a material included in the first alignment electrode ALE1 (or the second alignment electrode ALE2). In one or more embodiments, the first alignment electrode ALE1 (or the second alignment electrode ALE2) is connected to the second transistor electrode TE2, so that contact resistance of the alignment electrode can be reduced or minimized, and defects of the display device attributable to the contact resistance may be reduced.

The first insulating layer INS1 may be disposed on the via layer VIA to cover the first and second alignment electrodes ALE1 and ALE2. The first insulating layer INS1 may be disposed between the first alignment electrode ALE1 and the second alignment electrode ALE2, thus preventing a short circuit from occurring between the first alignment electrode ALE1 and the second alignment electrode ALE2. The first insulating layer INS1 may include inorganic material or organic material.

The light emitting element LD may be disposed on the first insulating layer INS1. The light emitting element LD may be an inorganic light emitting diode. The light emitting element LD may be aligned between the first alignment electrode ALE1 and the second alignment electrode ALE2 such that a first end EP1 of the light emitting element LD faces the first alignment electrode ALE1, and a second end EP2 thereof faces the second alignment electrode ALE2.

The first end EP1 of the light emitting element LD may partially overlap the first alignment electrode ALE1 in the third direction DR3. The second end EP2 of the light emitting element LD may partially overlap the second alignment electrode ALE2 in the third direction DR3. The present disclosure is not limited thereto.

The first bank BNK1 and the second bank BNK2 may be disposed on the first insulating layer INS1. The first bank BNK1 and the second bank BNK2 may form a dam structure configured to prevent a solution including the light emitting element LD from being drawn into the adjacent sub-pixels SPXL at the step of supplying the light emitting element LD onto the first insulating layer INS1, or to control the amount of solution such that a constant amount of solution is supplied to each sub-pixel SPXL. Furthermore, the first bank BNK1 and the second bank BNK2 may define an emission area EA of the subpixel SPXL. The first bank BNK1 and the second bank BNK2 may correspond to a single dam structure. The emission area EA may correspond to an opening area of the dam structure.

The first bank BNK1 and the second bank BNK2 may include organic material. In one or more embodiments, the first bank BNK1 and the second bank BNK2 may include light shielding material and/or reflective material. In this case, the first bank BNK1 and the second bank BNK2 may prevent light from leaking between the sub-pixel SPXL and sub-pixels adjacent thereto. For example, the first bank BNK1 and the second bank BNK2 may include a color filter material or a black matrix material. In one or more embodiments, in order to further enhance the efficiency of light emitted out of the sub-pixel SPXL, a separate reflective material layer may be provided and/or formed on the first bank BNK1 and the second bank BNK2.

A second insulating layer INS2 (or a second insulating pattern) may be disposed on the light emitting element LD. The second insulating layer INS2 may be disposed on a portion of the upper surface of the light emitting element LD such that the first end EP1 and the second end EP2 of the light emitting element LD are exposed to the outside. In one or more embodiments, the second insulating layer INS2 may also be disposed on the first insulating layer INS1 and/or the first and second banks BNK1 and BNK2.

The second insulating layer INS2 may include inorganic material or organic material, depending on design conditions of the display device including the light emitting element LD. After the alignment of the light emitting element LD on the first insulating layer INS1 has been completed, the second insulating layer INS2 is located on the light emitting element LD so that the light emitting element LD may be prevented from being removed from the aligned position. In the case where a gap (or space) is present between the first insulating layer INS1 and the light emitting element LD before the formation of the second insulating layer INS2, the gap may be filled with the second insulating layer INS2 during a process of forming the second insulating layer INS2.

The first pixel electrode ELT1 may be disposed on the first alignment electrode ALE1. The first pixel electrode ELT1 may directly contact the first end EP1 of the light emitting element LD. The second pixel electrode ELT2 may be disposed on the second alignment electrode ALE2. The second pixel electrode ELT2 may directly contact the second end EP2 of the light emitting element LD.

The first pixel electrode ELT1 and the second pixel electrode ELT2 may include at least one of various transparent conductive materials (or substances) including indium tin oxide (ITO), indium zinc oxide (IZO), zinc oxide (ZnOₓ), indium gallium zinc oxide (IGZO), and/or indium tin zinc oxide (ITZO), and may be substantially transparent or translucent to satisfy a certain transmittancy (or transmittance).

The second pixel electrode ELT2 may be brought into contact with or connected to the conductive pattern CP through a first contact hole CNT1 passing through the first insulating layer INS1, the via layer VIA, and the passivation layer PSV. The second pixel electrode ELT2 may electrically connect the second end EP2 of the light emitting element LD with the conductive pattern CP. Although FIG. 3 illustrates that the second pixel electrode ELT2 is connected to the conductive pattern CP through the first contact hole CNT1, the present disclosure is not limited thereto. The first pixel electrode ELT1 may be connected to the conductive pattern CP through the first contact hole CNT1.

The conductive pattern CP connected to the second pixel electrode ELT2 (or the first pixel electrode ELT1) may include the same material as the first and second pixel electrodes ELT1 and ELT2.

The second pixel electrode ELT2 (or the first pixel electrode ELT1) may be connected to the first transistor M1 by the conductive pattern CP through the first contact hole CNT1, so that the contact resistance of the pixel electrode may be reduced or minimized.

In one or more embodiments, the first and second pixel electrodes ELT1 and ELT2 may be physically separated from the first and second alignment electrodes ALE1 and ALE2.

FIGS. 4 to 11 are sectional views schematically illustrating a method of fabricating the display device in accordance with one or more embodiments of the present disclosure.

Referring to FIGS. 3 and 4, the bottom metal layer BML, the buffer layer BFL, the semiconductor pattern SCP, the conductive pattern CP, and a gate insulating layer GI′ of the pixel circuit layer PCL may be sequentially formed on the substrate SUB.

In one or more embodiments, the semiconductor pattern SCP and the conductive pattern CP may be formed on the buffer layer BFL through the same process. The semiconductor pattern SCP and the conductive pattern CP each may include an oxide semiconductor. The semiconductor pattern SCP and the conductive pattern CP may be formed by physical vapor deposition such as vacuum deposition or sputtering. In one or more embodiments, the semiconductor pattern SCP and the conductive pattern CP may employ a source having a composition similar to that of the oxide semiconductor layer. The source may be used as a target of a sputtering process. In one or more embodiments, the semiconductor pattern SCP and the conductive pattern CP may include at least one selected from among an indium gallium zinc oxide (IGZO) and/or an indium zinc titanium oxide (ITZO).

In one or more embodiments, the gate insulating layer GI′ may be formed on the overall surface of the substrate SUB.

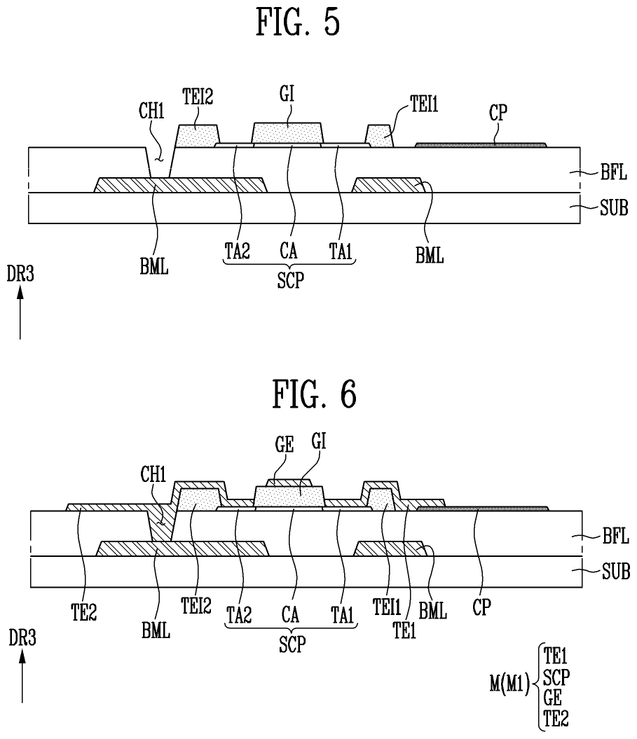

Referring to FIGS. 4 and 5, one area of the gate insulating layer GI′ may be removed.

In one or more embodiments, the gate insulating layer GI, the first electrode insulating layer TEI1, and the second electrode insulating layer TEI2 may be formed by etching (e.g., dry-etching) portions of the gate insulating layer GI′.

As some areas of the gate insulating layer GI′ are etched, one area of the semiconductor pattern SCP and the conductive pattern CP may be exposed. The conductive pattern CP and the first area TA1 and the second area TA2 of the semiconductor pattern SCP may be exposed. In one or more embodiments, the first area TA1 may be exposed to the outside between the first electrode insulating layer TEI1 and the gate insulating layer GI. The second area TA2 may be exposed to the outside between the second electrode insulating layer TEI2 and the gate insulating layer GI.

Furthermore, a contact hole CH1 may be formed in the buffer layer BFL by removing one area of the gate insulating layer GI′ and one area of the buffer layer BFL. The bottom metal layer BML may be exposed through the contact hole CH1.

Referring to FIG. 5, the conductive pattern CP and the first area TA1 and the second area TA2 of the semiconductor pattern SCP each may be doped to be a +N type dopant through a process of etching the gate insulating layer GI′. As the first and second areas TA1 and TA2 of the semiconductor pattern SCP and the conductive pattern CP each are doped to be an +N type, electrical resistance may be reduced.

In one or more embodiments, during a process of etching the gate insulating layer GI′, the conductive pattern CP may make a transition to a conductor having a conductivity level similar to that of metal. In the case where the conductive pattern CP is exposed to ultraviolet rays (or hydrogen gas), the charge mobility of the conductive pattern CP may be changed, thus making a transition to a conductor having a conductivity level similar to that of metal.

Referring to FIG. 6, the gate electrode GE, the first transistor electrode TE1, and/or the second transistor electrode TE2 may be formed.

In one or more embodiments, the gate electrode GE may be formed on the gate insulating layer GI.

In one or more embodiments, the first transistor electrode TE1 may be formed on the first electrode insulating layer TEI1. The first transistor electrode TE1 may be formed to overlap the first electrode insulating layer TEI1 and one area of the conductive pattern CP. The conductive pattern CP may be connected to and/or brought into contact with the first transistor electrode TE1.

In one or more embodiments, the second transistor electrode TE2 may be formed on the second electrode insulating layer TEI2. The second transistor electrode TE2 may be connected to the bottom metal layer BML through the contact hole CH1.

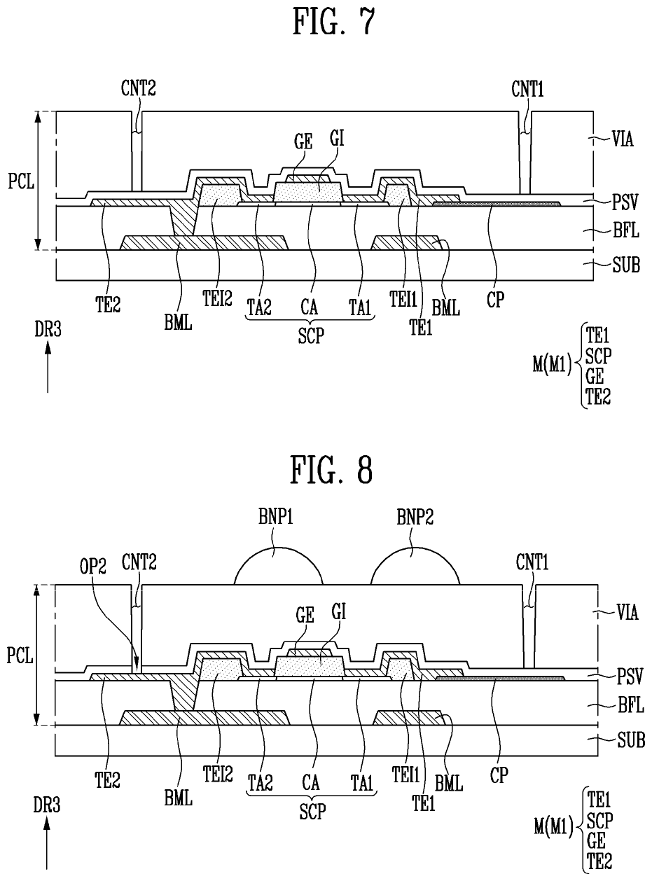

Referring to FIG. 7, the passivation layer PSV may be formed on the gate electrode GE, the first transistor electrode TE1, the second transistor electrode TE2, the conductive pattern CP, and the gate insulating layer GI. The via layer VIA may be formed on the passivation layer PSV.

Furthermore, the first contact hole CNT1 and the second contact hole CNT2 may be formed in the via layer VIA. In one or more embodiments, the first contact hole CNT1 may be a contact hole formed to connect the conductive pattern CP with the second pixel electrode ELT2 to be described below. The second contact hole CNT2 may be a contact hole formed to connect the second transistor electrode TE2 with the first alignment electrode ALE1 to be described below.

Referring to FIG. 8, the first bank pattern BNP1 and the second bank pattern BNP2 may be formed on the via layer VIA. Furthermore, one area of the passivation layer PSV that overlaps the second contact hole CNT2 may be removed. A second opening OP2 may be formed in one area of the passivation layer PSV. One area of the second transistor electrode TE2 that corresponds to the second opening OP2 may be exposed.

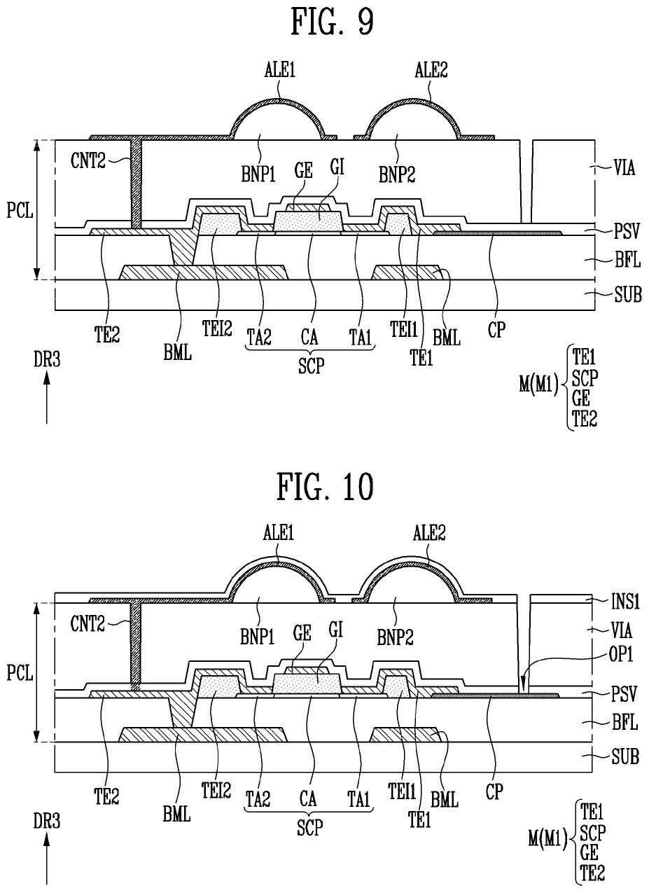

Referring to FIG. 9, the first alignment electrode ALE1 and the second alignment electrode ALE2 may be formed on the via layer VIA and the first and second bank patterns BNP1 and BNP2.

The first alignment electrode ALE1 may be formed to overlap the second contact hole CNT2 and the first bank pattern BNP1. The second alignment electrode ALE2 may be spaced from the first alignment electrode ALE1 and formed to overlap the second bank pattern BNP2.

In one or more embodiments, the second contact hole CNT2 and the second opening OP2 may be filled with the first alignment electrode ALE1. The first alignment electrode ALE1 may be connected to and/or brought into contact with the second transistor electrode TE2 through the second contact hole CNT2 and the second opening OP2.

Referring to FIG. 10, the first insulating layer INS1 may be formed on the via layer VIA and the first and second alignment electrodes ALE1 and ALE2. In one or more embodiments, one area of the passivation layer PSV that overlaps the first contact hole CNT1 may be removed. A first opening OP1 may be formed in one area of the passivation layer PSV. One area of the conductive pattern CP that corresponds to the first opening OP1 may be exposed.

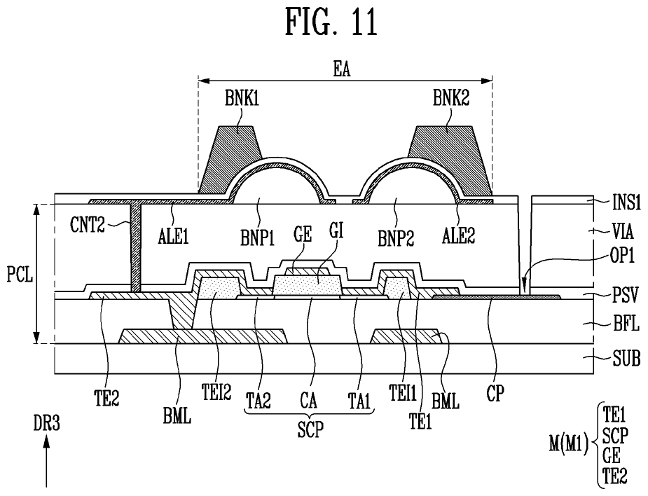

Referring to FIG. 11, the first bank BNK1 and the second bank BNK2 may be formed on the first insulating layer INS1.

After the first bank BNK1 and the second bank BNK2 are formed, a solution including the light emitting element LD may be supplied to the emission area EA formed by the first bank BNK1 and the second BNK2.

A sectional view pertaining to a process to be performed after the light emitting element LD is aligned between the first alignment electrode ALE1 and the second alignment electrode ALE2 in the method of fabricating the display device may correspond to FIG. 3. After the light emitting element LD is aligned between the first alignment electrode ALE1 and the second alignment electrode ALE2, a first pixel electrode (e.g., the first pixel electrode ELT1 of FIG. 3) and a second pixel electrode (e.g., the second pixel electrode ELT2 of FIG. 3) may be formed.

The second pixel electrode ELT2 may contact the second end EP2 of the light emitting element LD, and may be connected to the conductive pattern CP through the first contact hole CNT1 and the first opening OP1. The second pixel electrode ELT2 may be connected to the first transistor electrode TE1 through the conductive pattern CP and the second opening OP2.

In the display device in accordance with one or more embodiments of the present disclosure, the second pixel electrode ELT2 may be connected to the first transistor M1 by the conductive pattern CP, which is a conductor having a conductivity level similar to that of metal, so that the contact resistance and reactivity between the electrodes may be reduced or minimized. As the contact resistance and reactivity between the electrodes are reduced or minimized, the reliability of the display device may be enhanced.

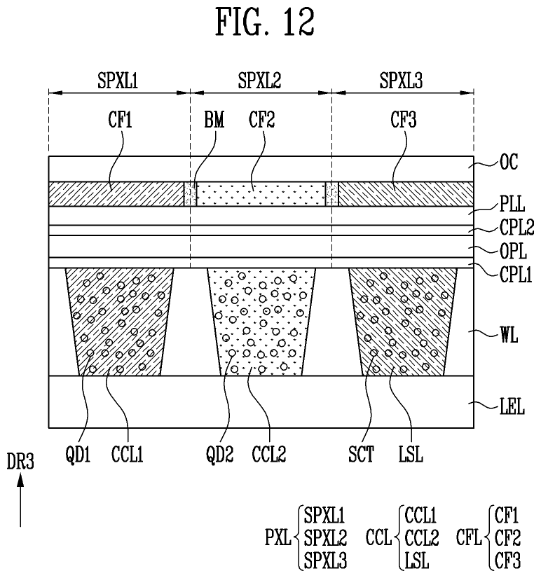

FIG. 12 is a sectional view illustrating first to third sub-pixels of FIG. 1 in accordance with one or more embodiments.

FIG. 12 illustrates a partition wall WL, a color conversion layer CCL, and/or a color filter layer CFL that are provided on the light emitting element layer LEL of the sub-pixel SPXL of FIG. 1.

The light emitting element layer LEL may be disposed on the display element layer DPL of FIG. 3.

Referring to FIG. 12, the partition wall WL may be disposed on the light emitting element layer LEL for the first to third sub-pixels SPXL1 to SPXL3. For example, the partition wall WL may be disposed between the first to third sub-pixels SPXL1 to SPXL3 or on boundaries therebetween, and include openings that respectively overlap the first to third sub-pixels SPXL1 to SPXL3. The openings of the partition wall WL may provide space in which the color conversion layer CCL can be provided.

The partition wall WL may include one or more organic materials such as acrylic resin, epoxy resin, phenolic resin, polyamide resin, polyimide resin, polyester resin, polyphenylene sulfide resin, and/or benzocyclobutene (BCB). However, the present disclosure is not limited thereto. The partition wall WL may include various inorganic materials including one or more selected from among silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and/or titanium oxide (TiOₓ).

The partition wall WL may include at least one light shielding and/or reflective material. Therefore, a light leakage between adjacent sub-pixels SPXL1 to SPXL3 may be prevented from being caused. For example, the partition wall WL may include at least one black matrix material and/or color filter material. For instance, the partition wall WL may be formed of a black opaque pattern that can block transmission of light. In one or more embodiments, a reflective layer or the like may be formed on a surface (e.g., a sidewall) of the partition wall WL to increase the light efficiency of each pixel PXL.

The color conversion layer CCL may be disposed on the light emitting element layer LEL including the light emitting elements LD in the openings of the partition wall WL. The color conversion layer CCL may include a first color conversion layer CCL1 disposed in the first sub-pixel SPXL1, a second color conversion layer CCL2 disposed in the second sub-pixel SPXL2, and a light scattering layer LSL disposed in the third sub-pixel SPXL3.

The first to third sub-pixels SPXL1 to SPXL3 may include light emitting elements LD configured to emit the same color of light. For example, the first to third sub-pixels SPXL1 to SPXL3 may include light emitting elements LD configured to emit the third color of light (or blue light). Because the color conversion layer CCL including color conversion particles is disposed in each of the first to third sub-pixels SPXL1 to SPXL3, a full-color image may be displayed.

The first color conversion layer CCL1 may include first color conversion particles for converting the third color of light emitted from the light emitting element LD to the first color of light. For example, the first color conversion layer CCL1 may include a plurality of first quantum dots QD1 that are diffused in a matrix material such as base resin.

In the case where the light emitting element LD is a blue light emitting element configured to emit blue light and the first pixel PXL1 is a red pixel, the first color conversion layer CCL1 may include the first quantum dots QD1 that convert blue light emitted from the blue light emitting element to red light. The first quantum dots QD1 may absorb blue light, shift the wavelength thereof according to an energy transition, and thus emit red light. In the case where the first color pixel PXL1 is a pixel of a different color, the first color conversion layer CCL1 may include the first quantum dots QD1 corresponding to the color of the first pixel PXL1.

The second color conversion layer CCL2 may include second color conversion particles for converting the third color of light emitted from the light emitting element LD to the second color of light. For example, the second color conversion layer CCL2 may include a plurality of second quantum dots QD2 that are dispersed in a matrix material such as base resin.

In the case where the light emitting element LD is a blue light emitting element configured to emit blue light and the second pixel PXL2 is a green pixel, the second color conversion layer CCL2 may include the second quantum dots QD2 that convert blue light emitted from the blue light emitting element to green light. The second quantum dots QD2 may absorb blue light, shift the wavelength thereof according to an energy transition, and thus emit green light. In case that the second color pixel PXL2 is a pixel of a different color, the second color conversion layer CCL2 may include the second quantum dots QD2 corresponding to the color of the second pixel PXL2.

As blue light having a relatively short wavelength in a visible ray area is incident on each of the first quantum dots QD1 and the second quantum dots QD2, absorption coefficients of the first quantum dot QD1 and the second quantum dot QD2 may be increased. Therefore, eventually, the efficiency of light emitted from the first sub-pixel SPXL1 and the second sub-pixel SPXL2 may be enhanced, and satisfactory color reproducibility may be secured. Furthermore, because the emission component EMU for the first to third sub-pixels SPXL1 to SPXL3 is formed of light emitting elements LD (e.g., blue light emitting elements) configured to emit the same color of light, the efficiency of fabricating the display device may be enhanced.

The light scattering layer LSL may be provided to efficiently use the third color of light (or blue light) emitted from the light emitting element LD. For example, in the case where the light emitting element LD is a blue light emitting element configured to emit blue light and the third sub-pixel SPXL3 is a blue pixel, the light scattering layer LSL may include at least one type of light scatterer SCT to efficiently use light emitted from the light emitting element LD.

For example, the light scattering layer LSL may include a plurality of light scatterers SCT that are diffused in a matrix material such as base resin. For instance, the light scattering layer LSL may include light scatterers SCT formed of material such as silica, but the constituent material of the light scatterers SCT is not limited thereto. The light scatterers SCT may not only be provided in the third sub-pixel SPXL3, but may also be selectively included in the first conversion layer CCL1 or the second color conversion layer CCL2. In one or more embodiments, the light scatterers SCT may be omitted, and the light scattering layer LSL may be formed of transparent polymer.

A first capping layer CPL1 may be disposed on the color conversion layer CCL. The first capping layer CPL1 may be provided over the first to third sub-pixels SPXL1 to SPXL3. The first capping layer CPL1 may cover the color conversion layer CCL. The first capping layer CPL1 may prevent the color conversion layer CCL from being damaged or contaminated by permeation of external impurities such as water or air.

The first capping layer CPL1 may be an inorganic layer, and may be formed of silicon nitride (SiNₓ), aluminum nitride (AlNₓ), titanium nitride (TiNx), silicon oxide (SiOₓ), aluminum oxide (AlOₓ), titanium oxide (TiOₓ), silicon oxycarbide (SiOₓCy), and/or silicon oxynitride (SiOₓN_{y}).

The optical layer OPL may be disposed on the first capping layer CPL1. The optical layer OPL may function to recycle light provided from the color conversion layer CCL by total reflection and thus enhance light extraction efficiency. Hence, the optical layer OPL may have a relatively low refractive index compared to that of the color conversion layer CCL. For example, the refractive index of the color conversion layer CCL may approximately range from 1.6 to 2.0, and the refractive index of the optical layer OPL may approximately range from 1.1 to 1.3.

A second capping layer CPL2 may be disposed on the optical layer OPL. The second capping layer CPL2 may be provided over the first to third sub-pixels SPXL1 to SPXL3. The second capping layer CPL2 may cover the optical layer OPL. The second capping layer CPL2 may prevent the optical layer OPL from being damaged or contaminated by permeation of external impurities such as water or air.

The second capping layer CPL2 may include inorganic material.

A planarization layer PLL may be disposed on the second capping layer CPL2. The planarization layer PLL may be provided over the first to third sub-pixels SPXL1 to SPXL3.

The planarization layer PLL may include one or more organic materials selected from among acrylic resin, epoxy resin, phenolic resin, polyamide resin, polyimide resin, polyester resin, polyphenylene sulfide resin, and/or benzocyclobutene (BCB). However, the present disclosure is not limited thereto, and the planarization layer PLL may include various types of inorganic materials.

The color filter layer CFL may be disposed on the planarization layer PLL. The color filter layer CFL may include color filters CF1, CF2, and CF3 corresponding to the colors of the respective pixels PXL. Because the color filters CF1, CF2, and CF3 corresponding to the respective colors of the first to third sub-pixels SPXL1 to SPXL3 are disposed, a full-color image may be displayed.

The color filter layer CFL may include a first color filter CF1 disposed in the first sub-pixel SPXL1 and configured to allow light emitted from the first sub-pixel SPXL1 to selectively pass therethrough, a second color filter CF2 disposed in the second sub-pixel SPXL2 and configured to allow light emitted from the second sub-pixel SPXL2 to selectively pass therethrough, and a third color filter CF3 disposed in the third sub-pixel SPXL3 and configured to allow light emitted from the third sub-pixel SPXL3 to selectively pass therethrough.

In one or more embodiments, the first color filter CF1, the second color filter CF2, and the third color filter CF3 may be respectively a red color filter, a green color filter, and a blue color filter, but the present disclosure is not limited thereto. Hereinafter, the term “color filter CF” or “color filters CF” will be used to designate any color filter from among the first color filter CF1, the second color filter CF2, and the third color filter CF3, or collectively designate two or more kinds of color filters.

The first color filter CF1 may overlap the light emitting element layer LEL (or the light emitting element LD) of the first sub-pixel SPXL1 and the first color conversion layer CCL1 in the third direction DR3. The first color filter CF1 may include a color filter material for allowing the first color of light (or red light) to selectively pass therethrough. For example, in the case in which the first sub-pixel SPXL1 is a red pixel, the first color filter CF1 may include a red color filter material.

The second color filter CF2 may overlap the light emitting element layer LEL (or the light emitting element LD) of the second sub-pixel SPXL2 and the second color conversion layer CCL2 in the third direction DR3. The second color filter CF2 may include a color filter material for allowing the second color of light (or green light) to selectively pass therethrough. For example, in the case in which the second sub-pixel SPXL2 is a green pixel, the second color filter CF2 may include a green color filter material.

The third color filter CF3 may overlap the light emitting element layer LEL (or the light emitting element LD) of the third sub-pixel SPXL3 and the light scattering layer LSL in the third direction DR3. The third color filter CF3 may include a color filter material for allowing the third color of light (or blue light) to selectively pass therethrough. For example, in the case in which the third sub-pixel SPXL3 is a blue pixel, the third color filter CF3 may include a blue color filter material.

In one or more embodiments, a light shielding layer BM (or a light shielding pattern) may be further disposed between the first to third color filters CF1, CF2, and CF3. In the case where the light shielding layer BM is formed between the first to third color filters CF1, CF2, and CF3, a color mixing defect, which is visible from a front surface or side surface of the display device, may be prevented from occurring. The material of the light shielding layer BM is not particularly limited, and various light shielding materials may be used to form the light shielding layer BM. For example, the light shielding layer BM may be embodied by stacking the first to third color filters CF1, CF2, and CF3 one on another.

An overcoat layer OC may be disposed on the color filter layer CFL. The overcoat layer OC may be provided over the first to third sub-pixels SPXL1 to SPXL3. The overcoat layer OC may cover a lower component including the color filter layer CFL. The overcoat layer OC may prevent water or air from permeating the lower component. Furthermore, the overcoat layer OC may protect the lower component from foreign material such as dust.

The overcoat layer OC may include an organic material. However, the present disclosure is not limited thereto, and the overcoat layer OC may include various types of inorganic materials.

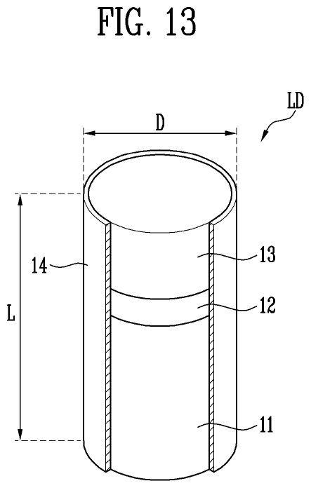

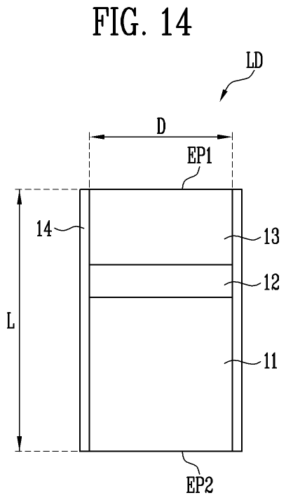

FIGS. 13 and 14 are diagrams each illustrating a light emitting element LD in accordance with one or more embodiments.

Referring to FIGS. 13 and 14, the light emitting element LD may include a first semiconductor layer 11, a second semiconductor layer 13, and an active layer 12 interposed between the first and second semiconductor layers 11 and 13. For example, the light emitting element LD may be implemented as an emission stack (or referred to as “stacked pattern”) formed by successively stacking the first semiconductor layer 11, the active layer 12, and the second semiconductor layer 13.

The light emitting element LD may be formed in a shape extending in one direction. If the direction in which the light emitting element LD extends is defined as a longitudinal direction, the light emitting element LD may have a first end EP1 and a second end EP2 with respect to the longitudinal direction. One semiconductor layer of the first semiconductor layer 11 and the second semiconductor layer 13 may be disposed on the first end EP1 of the light emitting element LD, and the other semiconductor layer of the first semiconductor layer 11 and the second semiconductor layer 13 may be disposed on the second end EP2 of the light emitting element LD.

The light emitting element LD may be provided in various shapes. For example, as illustrated in FIG. 13, the light emitting element LD may have a rod-like shape, a bar-like shape, or a pillar-like shape that is long with respect to the longitudinal direction (i.e., to have an aspect ratio greater than 1). Alternatively, the light emitting element LD may have a rod-like shape, a bar-like shape, or a pillar-like shape that is short with respect to the longitudinal direction (or has an aspect ratio less than 1). As a further alternative, the light emitting element LD may have a rod-like shape, a bar-like shape, or a pillar-like shape having an aspect ratio of 1.

The light emitting element LD may include a light emitting diode (LED) fabricated to have a subminiature size, e.g., with a diameter D and/or a length L corresponding to a range from the nano scale (or the nanometer scale) to the micro scale (or the micrometer scale).

In the case where the light emitting element LD is long (i.e., to have an aspect ratio greater than 1) with respect to the longitudinal direction, the diameter D of the light emitting element LD may approximately range from 0.5 μm to 6 μm, and the length L thereof may approximately range from 1 μm to 10 μm. However, the diameter D and the length L of the light emitting element LD are not limited thereto. The size of the light emitting element LD may be changed to meet requirements (or design conditions) of a lighting device or a self-emissive display device to which the light emitting element LD is applied.

The first semiconductor layer 11 may include, for example, at least one n-type semiconductor layer. The first semiconductor layer 11 may include, with respect to the longitudinal direction of the light emitting element LD, an upper surface that contacts the active layer 12, and a lower surface exposed to the outside. The lower surface of the first semiconductor layer 11 may correspond to one end (or a lower end) of the light emitting element LD.

The active layer 12 may be disposed on the first semiconductor layer 11 and have a single- or multi-quantum well structure. For example, in case that the active layer 12 is formed to have a multi-quantum well structure, the active layer 12 may be formed by periodically repeatedly stacking a barrier layer, a stain reinforcing layer, and a well layer that are provided as one unit. The stain reinforcing layer may have a lattice constant less than that of the barrier layer so that resistance to strain, e.g., compressive strain, to be applied to the well layer can be further reinforced. However, the structure of the active layer 12 is not limited to that of the foregoing embodiment.

The active layer 12 may emit light having a wavelength approximately ranging from 400 nm to 900 nm, and have a double hetero structure. The active layer 12 may include a first surface that contacts the first semiconductor layer 11, and a second surface that contacts the second semiconductor layer 13.

Depending on the wavelength of light emitted from the active layer 12, the color (or output light color) of the light emitting element LD may be determined. The color of the light emitting element LD may determine the color of the corresponding pixel. For example, the light emitting element LD may emit red light, green light, or blue light.

If an electric field having a certain voltage or more is applied between the opposite ends of the light emitting element LD, the light emitting element LD may emit light by coupling of electron-hole pairs in the active layer 12. Because light emission of the light emitting element LD can be controlled based on the foregoing principle, the light emitting element LD may be used as a light source (a light emitting source) of various light emitting devices as well as a pixel of a display device.

The second semiconductor layer 13 may be disposed on the second surface of the active layer 12 and include a semiconductor layer of a type different from that of the first semiconductor layer 11. For example, the second semiconductor layer 13 may include at least one p-type semiconductor layer.

The second semiconductor layer 13 may include, with regard to the longitudinal direction of the light emitting element LD, a lower surface that contacts the second surface of the active layer 12, and an upper surface exposed to the outside. Here, the upper surface of the second semiconductor layer 13 may correspond to a remaining end (or an upper end) of the light emitting element LD.

The first semiconductor layer 11 and the second semiconductor layer 13 may have different thicknesses with respect to the longitudinal direction of the light emitting element LD. For example, the first semiconductor layer 11 may have a thickness greater than that of the second semiconductor layer 13 with respect to the longitudinal direction of the light emitting element LD. Hence, the active layer 12 of the light emitting element LD may be disposed at a position closer to the upper surface of the second semiconductor layer 13 than to the lower surface of the first semiconductor layer 11.

Although the first semiconductor layer 11 and the second semiconductor layer 13 each are formed of a single layer, the present disclosure is not limited thereto. In one or more embodiments, depending on the material of the active layer 12, the first semiconductor layer 11, and the second semiconductor layer 13 each may further include one or more layers, for example, a clad layer and/or a tensile strain barrier reducing (TSBR) layer. The TSBR layer may be a strain relief layer that is disposed between semiconductor layers having different lattice structures and thus can function as a buffer layer to reduce a difference in lattice constant. Although the TSBR layer may be formed of a p-type semiconductor layer such as p-GaInP, p-AllnP, or p-AlGaInP, the present disclosure is not limited thereto.

The light emitting element LD may further include a contact electrode (hereinafter referred to as “first contact electrode”) disposed over the second semiconductor layer 13, as well as including the first semiconductor layer 11, the active layer 12, and the second semiconductor layer 13. Furthermore, in one or more embodiments, the light emitting element LD may further include an additional contact electrode (hereinafter referred to as “second contact electrode”) disposed on one end of the first semiconductor layer 11.

Each of the first and second contact electrodes may be an ohmic contact electrode, but the present disclosure is not limited thereto. In one or more embodiments, each of the first and second contact electrodes may be a Schottky contact electrode. The first and second contact electrodes may include conductive material.

The light emitting element LD may further include an insulating layer 14 (or referred to as “insulating film”). However, in one or more embodiments, the insulating layer 14 may be omitted, or may be provided to cover only some of the first semiconductor layer 11, the active layer 12, and the second semiconductor layer 13.

The insulating layer 14 may prevent the active layer 12 from short-circuiting due to making contact with conductive material except the first and second semiconductor layers 11 and 13. Furthermore, the insulating layer 14 may reduce or minimize a surface defect of the light emitting element LD, thus enhancing the lifetime and emission efficiency of the light emitting element LD. The presence or non-presence of the insulating layer 14 is not limited, so long as the active layer 12 can be prevented from short-circuiting with external conductive material.

The insulating layer 14 may be provided to be around (e.g., to enclose) at least a portion of an outer surface (e.g., an outer peripheral or circumferential surface) of the emission stack including the first semiconductor layer 11, the active layer 12, and the second semiconductor layer 13.

Although in the foregoing embodiment, the insulating layer 14 has been described as enclosing the entirety of the outer surface (e.g., an outer peripheral or circumferential surface) of each of the first semiconductor layer 11, the active layer 12, and the second semiconductor layer 13, the present disclosure is not limited thereto.

The insulating layer 14 may include transparent insulating material. For example, the insulating layer 14 may include one or more insulating materials selected from the group of silicon oxide (SiOₓ), silicon nitride (SiNₓ), silicon oxynitride (SiOₓN_{y}), aluminum oxide (AlOₓ), titanium oxide (TiOₓ), hafnium oxide (HfOₓ), titanstrontium oxide (SrTiOₓ), cobalt oxide (CoₓO_{y}), magnesium oxide (MgO), zinc oxide (ZnOₓ), ruthenium Oxide (RuOₓ), nickel oxide (NiO), tungsten oxide (WOₓ), tantalum oxide (TaOₓ), gadolinium oxide (GdOₓ), zirconium oxide (ZrOₓ), gallium oxide (GaOₓ), vanadium oxide (VₓO_{y}), ZnO:Al, ZnO:B, InxOy:H, niobium oxide (NbₓO_{y}), magnesium fluoride (MgFₓ), aluminum fluoride (AlFₓ), an alucone polymer film, titanium nitride (TiN), tantalum nitride (TaN), aluminum nitride (AlNₓ), gallium nitride (GaN), tungsten nitride (WN), hafnium nitride (HfN), niobium nitride (NbN), gadolinium nitride (GdN), zirconium nitride (ZrN), and/or vanadium nitride (VN). However, the present disclosure is not limited thereto, and various materials having insulation may be used as the material of the insulating layer 14.

The insulating layer 14 may have a single-layer structure or a multi-layer structure including a double-layer structure.

The light emitting element LD may be employed as a light emitting source (or a light source) for various display devices. The light emitting element LD may be fabricated through a surface treatment process. For example, the light emitting element LD may be surface-treated so that, when a plurality of light emitting elements LD are mixed with a fluidic solution (or solvent) and then supplied to each pixel area (e.g., an emission area of each pixel or an emission area of each sub-pixel), the light emitting elements LD can be evenly distributed rather than unevenly aggregating in the solution.

An emission component (or a light emitting device) including the light emitting elements LD described above may be used not only in a display device but also in various types of electronic devices each of which requires a light source. For instance, in the case where a plurality of light emitting elements LD are disposed in the pixel area of each pixel of a display panel, the light emitting elements LD may be used as a light source of the pixel. However, the application field of the light emitting element LD is not limited to the above-mentioned examples. For example, the light emitting element LD may also be used in other types of electronic devices such as a lighting device, which requires a light source.

However, the foregoing is only for illustrative purposes, and the light emitting element LD in accordance with one or more embodiments of the present disclosure is not limited thereto. For example, the light emitting element may be a flip chip type micro light emitting diode, or an organic light emitting element including an organic emission layer.

In a display device in accordance with embodiments of the present disclosure, a pixel electrode may be connected to a transistor through a conductive pattern doped with a semiconductor material, so that contact resistance and reactivity between electrodes may be reduced or minimized. As the contact resistance and reactivity between the electrodes are reduced or minimized, the reliability of the display device may be enhanced.

However, effects, aspects, and features of the present disclosure are not limited to the above-described effects, aspects, and features, and various modifications are possible without departing from the spirit and scope of the present disclosure.

While embodiments of the present disclosure have been described above, those skilled in the art will appreciate that various modifications, additions, and substitutions are possible, without departing from the scope and spirit of the present disclosure claimed in the appended claims.

What is claimed is:

1. A display device comprising:
a pixel circuit layer comprising a first transistor and a conductive pattern; and
a display element layer on the pixel circuit layer, and comprising a light emitting element,
wherein the display element layer further comprises:
a first pixel electrode electrically connected to a first end of the light emitting element; and
a second pixel electrode electrically connected to a second end of the light emitting element,
wherein the first transistor comprises:
a semiconductor pattern;
a first gate insulating layer on the semiconductor pattern;
a gate electrode on the first gate insulating layer; and
a first transistor electrode and a second transistor electrode connected to the semiconductor pattern,
wherein the conductive pattern is at a same layer as the semiconductor pattern, and
wherein the first transistor electrode is connected to the second pixel electrode by the conductive pattern.

2. The display device according to claim 1, wherein each of the semiconductor pattern and the conductive pattern comprises an indium gallium zinc oxide (IGZO).

3. The display device according to claim 2, wherein the semiconductor pattern is physically separated from the conductive pattern.

4. The display device according to claim 3, wherein the conductive pattern is doped with a semiconductor material.

5. The display device according to claim 4, wherein the semiconductor pattern and the conductive pattern are doped with a same dopant.

6. The display device according to claim 4, wherein the display element layer further comprises:
a second gate insulating layer covering a portion of a first doping area of the semiconductor pattern; and
a third gate insulating layer covering one area of a second doping area of the semiconductor pattern,
wherein the first transistor electrode is on the second gate insulating layer, and
wherein the second transistor electrode is on the third gate insulating layer.

7. The display device according to claim 6, wherein the first transistor electrode, the second transistor electrode, and the gate electrode comprise a same material.

8. The display device according to claim 6, wherein an overall surface of the conductive pattern is exposed from the first gate insulating layer, the second gate insulating layer, and the third gate insulating layer.

9. The display device according to claim 1, wherein the display element layer comprises:
a first alignment electrode under the first pixel electrode; and
a second alignment electrode under the second pixel electrode,
wherein the first alignment electrode or the second alignment electrode is directly connected to the second transistor electrode.

10. The display device according to claim 9, wherein the pixel circuit layer comprises:
a substrate;
a bottom metal layer on the substrate, and overlapping a channel area of the semiconductor pattern; and
a buffer layer covering the bottom metal layer,
wherein the first transistor is on the buffer layer, and
wherein the second transistor electrode is electrically connected to the bottom metal layer through a contact hole.

11. The display device according to claim 10, wherein the pixel circuit layer further comprises:
a passivation layer covering the first transistor; and
a via layer on the passivation layer,
wherein the display element layer further comprises:
a first bank pattern on the via layer, and a second bank pattern at a same layer as the first bank pattern,
wherein the first alignment electrode overlaps the first bank pattern,
wherein the second alignment electrode overlaps the second bank pattern, and
wherein the light emitting element is between the first bank pattern and the second bank pattern.

12. The display device according to claim 11, wherein the first alignment electrode or the second alignment electrode is electrically connected to the second transistor electrode through a first contact hole passing through the passivation layer and the via layer.

13. The display device according to claim 9,
wherein the display element layer further comprises an insulating layer covering the first alignment electrode and the second alignment electrode,
wherein the first pixel electrode overlaps the first alignment electrode on the insulating layer, and
wherein the second pixel electrode overlaps the second alignment electrode on the insulating layer.

14. The display device according to claim 13, wherein the second pixel electrode is directly connected to the conductive pattern through a second contact hole passing through the insulating layer, the via layer, and a passivation layer covering the first transistor.

15. The display device according to claim 1, wherein the light emitting element comprises a first semiconductor layer, a second semiconductor layer, and an active layer between the first semiconductor layer and the second semiconductor layer.

16. A method of fabricating a display device, comprising:
forming a semiconductor pattern and a conductive pattern on a substrate;
forming a gate insulating layer on overall surfaces of the semiconductor pattern and the conductive pattern;
exposing a portion of the semiconductor pattern and the conductive pattern by removing one area of the gate insulating layer;
forming a first transistor electrode, a second transistor electrode, and a gate electrode on the semiconductor pattern;
forming a via layer covering the first transistor electrode, the second transistor electrode, the gate electrode, and the conductive pattern;
disposing a light emitting element on the via layer; and
forming a first pixel electrode electrically connected to a first end of the light emitting element, and a second pixel electrode electrically connected to a second end of the light emitting element,
wherein the first pixel electrode is directly connected to the conductive pattern.

17. The method according to claim 16, wherein each of the semiconductor pattern and the conductive pattern comprises an indium gallium zinc oxide (IGZO).

18. The method according to claim 16, wherein exposing the portion of the semiconductor pattern comprises doping one area of the semiconductor pattern exposed through a process of etching another area of the gate insulating layer.

19. The method according to claim 17, further comprising:
forming a second contact hole by removing one area of the via layer that overlaps the second transistor electrode; and
disposing, on the via layer, a first alignment electrode and a second alignment electrode spaced apart from the first alignment electrode,
wherein the first alignment electrode is connected to the second transistor electrode through the second contact hole.

20. The method according to claim 16, wherein the semiconductor pattern and the conductive pattern comprise a same material, and are concurrently formed.
